(19) United States
(12) Patent Application Publication
(10) Pub. No.: US 2019/0080891 A1
(43) Pub. Date: Mar. 14, 2019

(54) COATER

(71) Applicant: GENCOA LTD, Speke, Liverpool (GB)

(72) Inventor: Victor Bellido-Gonzalez, Liverpool (GB)

(73) Assignees: GENCOA LTD, Speke, Liverpool, ME (GB); GENCOA LTD, Speke, Liverpool, ME (GB)

(21) Appl. No.: 16/079,307

(22) PCT Filed: Feb. 24, 2017
(86) PCT No.: PCT/GB2017/050504

§ 371 Date: Aug. 23, 2018

(30) Foreign Application Priority Data
Feb. 24, 2016 (GB) 1603233.6

(51) Int. Cl. H01J 37/34; H01J 37/32

(52) U.S. Cl. CPC H01J 37/3452; H01J 2237/332; H01J 37/3233; H01J 37/3438

(57) ABSTRACT

This invention relates to generation and control of electron emission and transport in a plasma device for enhancing ionization in sputtering, including magnetron sputtering, ion treatment, thermal evaporation, electron beam evaporation. The device in combines a sputtering enhanced electron emission on a cathodic element in which a strong electrical field around the electron emission element is created. In addition, this electric field area is in a magnetically confined space of nearly null strength and/or magnetic mirror features. The electron emission area would also comprise of guided magnetic field extraction magnetic field paths which could be either permanent or created at pulse modes. Also, the invention relates to reactive process and coating deposition ion bombardment management. This invention also relates to the use in feedback control systems; manufacturing process and methods which use these devices and materials and components processed by the present invention are also part of the invention.

### TECHNICAL FIELD

This invention relates a coater, which may be an ionisation enhancement device. In particular, but without limitation, this invention relates to the generation and control of electron emission and transport in a plasma device for the purpose of enhancing ionisation in sputtering; magnetron sputtering; variations of ion treatment, thermal evaporation, sublimation deposition, electron beam evaporation, chemical vapour deposition (CVD), and plasma assisted chemical vapour deposition (PACVD).

The invention, in certain embodiments, combines a sputtering-enhanced electron emission on a hot cathodic element in which a strong electrical field around the hot element is created. In addition, this electric field area is in a magnetically confined space of nearly null strength and/or magnetic mirror features. The electron emission area of the hot cathode element could also comprise of guided magnetic field extraction magnetic field paths which could be either constant/continuous/permanent or created in pulses (pulse modes).

Also, the invention may relate to reactive process and coating deposition ion bombardment management. This invention may also relate to the use of present device in feedback control systems; manufacturing process and methods which use these devices and materials and components processed by the present invention are also part of the invention.

### BACKGROUND ART

It is known that electron emission from a conductor into vacuum is stimulated by high temperature and high negative voltage on the conductor. High electron current could be managed in order to produce electron beam evaporation from a material in a crucible. A family of these hot electrical conductors is based on hot filaments, in which the high temperature requirements are easy to achieve at relatively low currents due to the small cross section of the conductor wire. Hot filaments have been used extensively in Chemical Vapour Deposition (Hot Filament CVD) and in enhancing ionisation of evaporated material such as in Hot Filament Ionisation Enhanced Electron Beam Evaporation. With regard to Hot Filament CVD, the hot filament itself would not be biased for the purpose of any electron emission but rather act as a thermal molecular cracker assisting the chemical reaction and coating deposition. With regard to electron beam evaporation, the assistance of an additional biased hot filament would provide an electron injection into the process. Due to the nature of the discharge this emission is not confined or channeled in any particular direction.

However, the present invention by magnetic, electric and plasma collisions may be able to enhance the electron emission of the hot element, such as a hot filament, at the same time as providing confinement, ionisation and electron and ion guidance. The present invention could be used in conjunction with other vacuum deposition techniques. In addition, the degree of confinement and interaction with other materials could be varied according to the present invention.

The present invention also relates to the use of the elements of electron generation, confinement, and guidance for planar, cylindrical rotatable and any other type of sputtering cathodic technique.

The present invention also relates to the use of the elements of electron generation, confinement, and guidance in reactive and non-reactive processes. The reactive processes being those which would involve the presence, although not exclusively, of a non-inert gas such as O₂ or N₂.

### DISCLOSURE OF THE INVENTION

Various aspects of the invention are set forth in the appended independent claims. Various preferred, suitable, or optional features of the invention are set forth in the appended dependent claims.

According to one aspect of the present invention, an electron injection ionisation enhancement device is provided. The electron emission can be provided from a cathodic element (also referred to herein as a thermionic emitter) which is capable of providing secondary electron emission under ionic bombardment. The cathodic element would typically be of a refractory nature (high melting point), able to operate at high temperature in vacuum conditions with very low vapour pressure and low sputtering yield at the same time as having a significant secondary electron emission during ion bombardment conditions. Materials could be, although are not exclusively, tungsten, borides such as ZrB₂, TiB₂. According to certain aspects of the present invention, the cathodic element is placed in an area of magnetic field confinement having an intensity of zero, or near zero. This near zero confinement suitably allows low sputtering degradation of the cathodic element. In addition, a magnetic field retention volume with electro-magnetic mirroring and magnetic field guidance could create an electron-rich zone where electrons are essentially confined and ionisation collisions occur. In addition to the confinement, an electron escape path, or a preferential electron escape path, could also be part of the present invention. The electron escape path may provide ion escape. By guiding the electrons into contact with coating elements, ionisation, or plasma activation of species preferably occurs.

According to another aspect of the invention, there is provided a coater comprising: a vapour supply; a thermionic emitter located adjacent to, but spaced apart from, the vapour supply; an anode located on an opposite side of the thermionic emitter to the vapour supply; biasing means adapted in use, to negatively bias the thermionic emitter with respect to the anode; and magnetic means adapted, in use, to create a magnetic field; wherein the magnetic field comprises: a region of low magnetic field strength around the thermionic emitter; and a region of magnetic field extending between the vapour supply and the anode, such that, in use, electrons emitted by the thermionic emitter: interact with the vapour supply to cause emission of a vapour from the vapour supply and at least partially ionise the vapour from the vapour supply—thereby forming an at least partially ionised vapour flux; are attracted to the anode, thereby forming an electron flux towards the anode, the electron flux being at least partially confined within the region of magnetic field extending between the vapour supply and the anode and wherein: the resulting at least partially confined electron flux interacts with the at least partially ionised vapour flux to guide the latter in a direction towards the anode and preferentially along a path corresponding to the region of magnetic field extending between the vapour supply and the anode.

In certain respects, the result of the invention is preferably an improved and/or alternative coater, which enhances the directionality of the flux of ionised material by channeling it through the region of magnetic field extending between the vapour supply and the anode.

The region of magnetic field extending between the vapour supply and the anode is preferably a region of low, near-zero or zero magnetic field strength, which extends between the vapour supply and the anode; in which case, the result of the invention is most preferably an improved and/or alternative coater, which enhances the directionality of the flux of ionised material by channeling it through a region of low magnetic field strength extending between the vapour supply and the anode.

Suitably, the vapour flux comprises a vapour of material, which can be, but not exclusively, a molecular vapour, a vapour of atoms, a vapour of compounds, etc., the material being vaporised/evaporated from the vapour supply. The vapour supply can be a target manufactured from a material which it is desired to coat onto a substrate. The vapour supply can take the form of a crucible, containing the material to be coated onto a substrate, in certain embodiments. The material vapour is suitably supplied by suitable means such as thermal evaporation, electron beam evaporation, sputtering, magnetron sputtering, gas or vapour injection.

The thermionic emitter is cathodic with respect to the anode, and the biasing means is preferably adapted in use, to negatively bias the thermionic emitter (cathode) with respect to the anode, thereby creating an electric field between the thermionic emitter (cathode) and the anode.

Preferably, the magnetic field comprises a magnetic field trap. Preferably, the magnetic field, and/or the region of magnetic field extending between the between the supply of a material to be supplied and the anode comprises, or forms, electron mirror. In the context of this disclosure, a “magnetic mirror” is a type of magnetic confinement device, that can trap the at least partially ionised vapour flux and/or the electron flux (which may together, or individually, be a plasma) using magnetic fields. The magnetic field is suitably configured such that it (i.e. its magnetic field lines) reflect charged particles from a high density magnetic field region to a low density magnetic field region. The operation of magnetic mirrors will be well-understood by the skilled reader, but the principle of operation is such that a charged particle moving within a region of magnetic field experiences a Lorentz force that causes it to move in a helical path along a magnetic field line. As the charged particle moves through a magnetic field gradient, the combination of the radial component of the fields and the azimuthal motion of the particle results in a force pointed against the magnetic field gradient, in the direction of lower magnetic field strength. It is this force that can reflect the charged particle, thus causing it to decelerate and, in certain cases, reverse direction.

The invention thus differs from existing coaters, and/or electron beam evaporators, insofar as the thermionic emitter is located between the vapour supply and the cathode in an area of magnetic confinement such as is able to self-generate the electric field necessary to ionise and guide the ions towards a substrate region.

The invention is contraindicated because, according to accepted wisdom, a thermionic emitter actually placed inside the coater would be susceptible to considerable ablation/erosion/wear due to the operating conditions within a known coater. Also, the electron emission lacks entrapment with a lower degree of ionisation. However, because, in the invention, the thermionic emitter is located in a region of low magnetic field strength, it is effectively protected from sputter erosion by the magnetic field, which reduces strong ion bombardment of the thermionic emitter, and thus reduces or eliminates undue wear or premature failure of the thermionic emitter.

Thermionic emission is a process whereby electrons are emitted from a hot cathode, usually under vacuum conditions. The phenomenon is also known as thermal electron emission or the “Edison effect”. In the context of the present disclosure, term “thermionic emitter” is to be construed as being any device, which emits electrons when heated. Suitably, the thermionic emitter comprises a filament, which can be heated, for example, by passing an electrical current through it. Suitably, the thermionic emitter comprises a filament, which is preferably manufactured of a refractory material, such as tungsten, FeCrAl alloy, molybdenum, silicides (e.g. MoSi2), carbides (e.g. SiC) or borides (e.g. ZrB₂ of TiB₂).

In the context of the present disclosure, the region of low magnetic field strength around the thermionic emitter suitably comprises a region of magnetic confinement having a very low, near-zero, or zero magnetic field strength. Likewise, the region of low magnetic field strength extending between the vapour supply and the anode suitably comprises a region of electron mirror magnetic confinement having a stronger magnetic field strength to that of the low, near-zero, or zero field strength region.

In preferred embodiments of the invention, the region or regions of magnetic confinement is/are bounded by a region or regions of relatively higher magnetic field strength, which may form one or more “plasma traps” around the region(s) of magnetic confinement. Suitably, this configuration creates a “barrier” adjacent the confinement regions, which inhibits or prevents the flux electrons and in doing so the ionised material vapour which follows the electric field induced by the electron movement from the supply of material vapour from entering it.

The biasing means may comprise an electrical power supply operatively connected to the anode and thermionic emitter. Any type of power supply may be used, such as a low-voltage DC power supply; a high-voltage DC power supply, an AC power supply, etc. Various parameters of the power supply can optionally be varied, either manually or automatically, such as the magnitude, frequency, phase, pulse duration, etc. of the applied voltage or resulting current/field.

An additional electrode may also be provided, which can be located on an opposite side of the vapour supply from the thermionic emitter. The additional electrode, where provided, is suitably designed/configured so as to sustain a plasma discharge and/or an electron emission and/or ionised particles and/or neutral particles. At least some of those particles may preferably have energies above about 5 eV. The additional electrode could be static or dynamic, and of different geometry, for example it could be a planar target, or tubular/cylindrical.

In order to coat a substrate using the evaporator, means for retaining a substrate is suitably provided. This may take any suitable form, such as a fixed substrate holder; a moving substrate holder; a linearly-moving substrate holder; a rotationally moving substrate holder; a carousel; and a multi-axis carousel.

To improve, modify or enhance a coating process, the evaporator may further comprise a secondary vapour supply (source of a secondary material to be evaporated), which can be arranged to emit a flux of the secondary material towards the substrate.

The evaporator is preferably operated in a controlled atmosphere, such as in a vacuum or partial vacuum, and/or with one or more reactive or non-reactive gasses present. A housing enclosing the evaporator may thus be provided, which may also, in certain embodiments, comprise an atmosphere control means for controlling an atmosphere within the housing. The atmosphere control means could comprise a vacuum pump for at least partially evacuating the housing and/or a gas delivery system for at least partially filling the housing with a process gas. Suitably process gasses are non-inert gases, such as O₂ or N₂.

The magnetic means may be of any suitable type, but in certain embodiments, the magnetic means comprise one or more permanent magnets. Additionally or alternatively, the magnetic means may comprise one or more electromagnets. Additionally or alternatively, the magnetic means may comprise one or more ferromagnetic elements that modify, in use, the shape of the magnetic field.

As will be understood from the following description, the invention could be incorporated into a system comprising a plurality of evaporators as herein described. Suitably, the plurality of evaporators are arranged such that their respective regions of low magnetic field strength extending between their respective supplies of a material to be evaporated and their respective anodes converge and/or overlap and/or meet at an intersection point in space. In certain embodiments, a common anode is provided, which is shared by one or more of the plurality of evaporators. Additionally, a supplementary magnetic means may be provided, which is adapted, in use, to modify the shape of the respective magnetic fields of the plurality of evaporators.

In one of the embodiments of the present invention the elements responsible for the electron injection, confinement, ionisation collision and guidance could change the nature of the injection, confinement, ionisation collisions and plasma guidance, in such a way that different degree of control in the plasma properties and plasma interaction with coating elements could be changed.

In another part of the present invention, this invention also relates to a feedback control system that uses this type of electron injection and ionisation enhancement device.

In another part of the present invention, this invention also relates to the use of one or a plurality of these electron emission and confinement devices.

The present invention could relate to planar and or cylindrical rotatable cathodes.

In other embodiment of the present invention the electron injection element could be integrated within the confinement or outside the confinement of a coating element.

This invention also relates to materials, components and devices manufactured by methods which use these confined electron emission ion devices.

### BRIEF LISTING OF THE DRAWINGS

The invention will be further described by way of example only with reference to the following figures in which:

FIG. 1 is a schematic representation of a known vacuum deposition system based on electron beam evaporation; and

FIGS. 2 to 10 are schematic diagrams illustrating various embodiments of the invention.

### DETAILED DESCRIPTION OF THE DRAWINGS

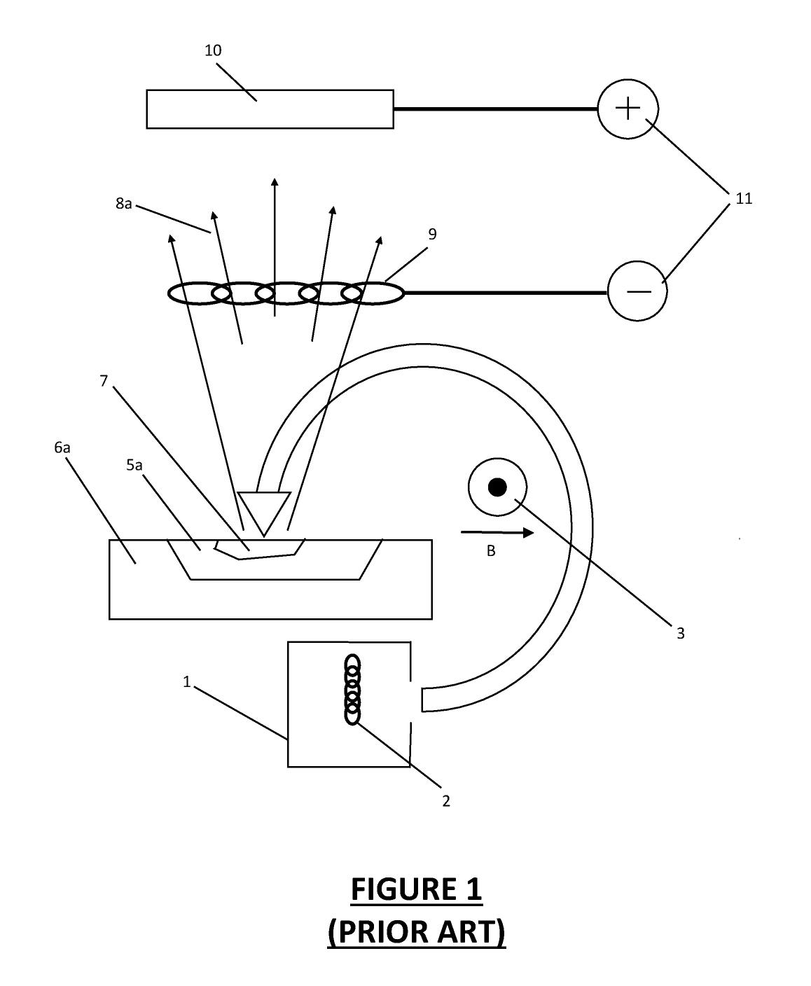

Referring to the drawings, FIG. 1 shows a schematic representation of a vacuum deposition system based on electron beam evaporation as described by previous art. In this example, a device 1 contains a hot element 2 able to produce an electron beam emission, which is guided via a magnetic field 3 (indicated in the drawings by a set of magnetic field lines joining points of equal magnetic field strength) through a path 4. The path 4 guides the electron beam towards a crucible 6a containing a material 5a which, under impact, heats up. The zone of heating 7 sublimates/evaporates the material. The evaporated material 8a follows directions of travel: some of them crossing over a space where a cathodic hot element 9 is biased negatively at a differential voltage with respect to an anode 10 via suitable power supply 11. The electron emission of the cathodic hot element 9a is substantially isotropic, provided that enough distance from the magnetic field 3 is present. The collision between evaporated elements and/or gas particles and the electrons produces a degree of ionisation of species present in the vacuum.

The remaining Figures, elucidated below, relate to various different embodiments/versions/variants of coaters in accordance with the invention.

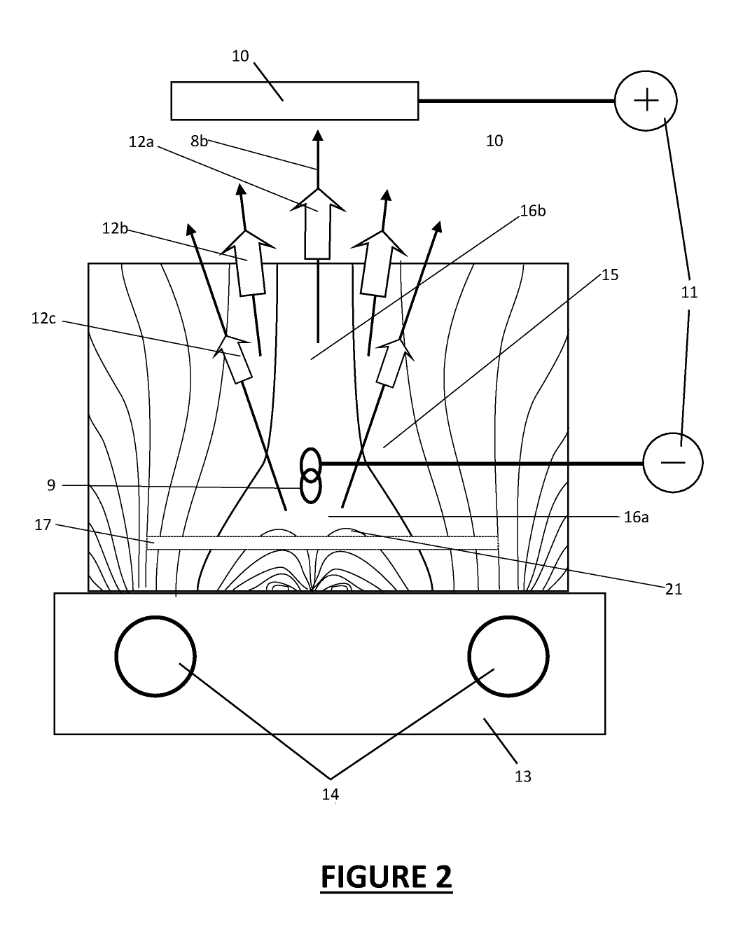

FIG. 2 shows a schematic of a coater in accordance with the present invention. A device 13 able to control electron emission and plasma is disclosed. In such device, a cathodic element 9, being a thermionic emitter, is placed in a partially evacuated atmosphere and in an area of magnetic field confinement 16a. Thermionic emitter 9 is biased negatively with respect to the anodic element 10 via suitable power supply 11. Electrons emitted by thermionic emitter 9 are essentially trapped by a magnetic field (denoted in the drawings by a set of magnetic field lines joining points of equal magnetic field strength) 21 and 15 and negatively biased element 17.

In addition, magnetic field trap 21 could be varied by magnetic means 14. In addition, biasing on the element 17 could also be used to sustain a plasma discharge and/or an electron emission and/or ionised particles and/or neutral particles with at least some of those particles having energies above 5 eV.

The confinement of electrons around the thermionic emitter 9 is such that the electrons are channeled towards the anode 10 via a guided path 16b created by the magnetic field lines 15. Collision between electrons and gas and/or other elemental and/or molecular particles 8b present in the vacuum produces, ordinarily, a degree of ionisation. Ionised particles will be guided by the flow of electrons towards the anode creating a major ionisation flux 12a. Other ionised particles could follow a different type of distribution such as in directions indicated by arrows 12b-12c-mainly based on the energy and momentum conservation and collisions occurring in the process.

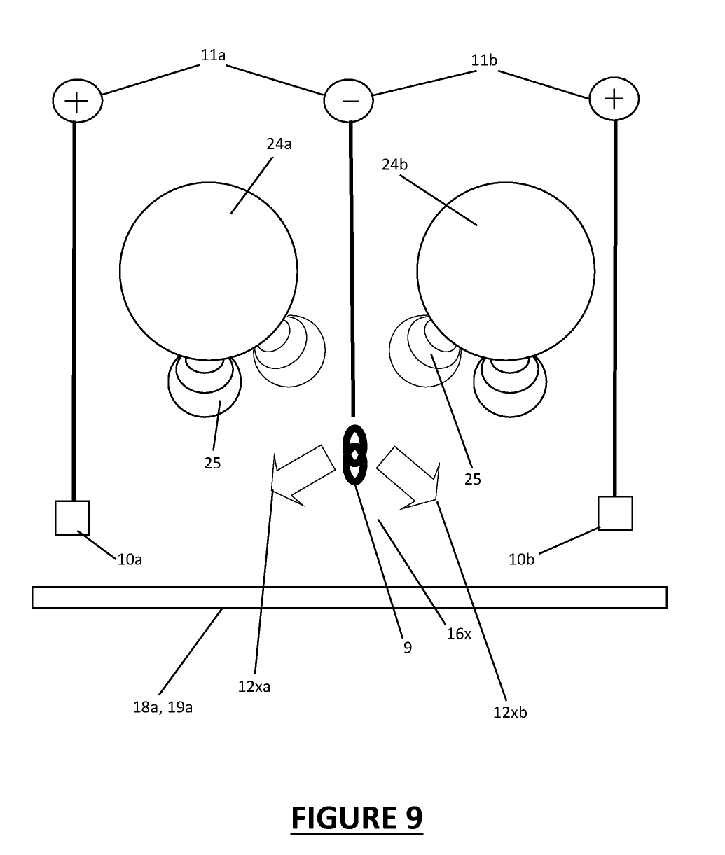

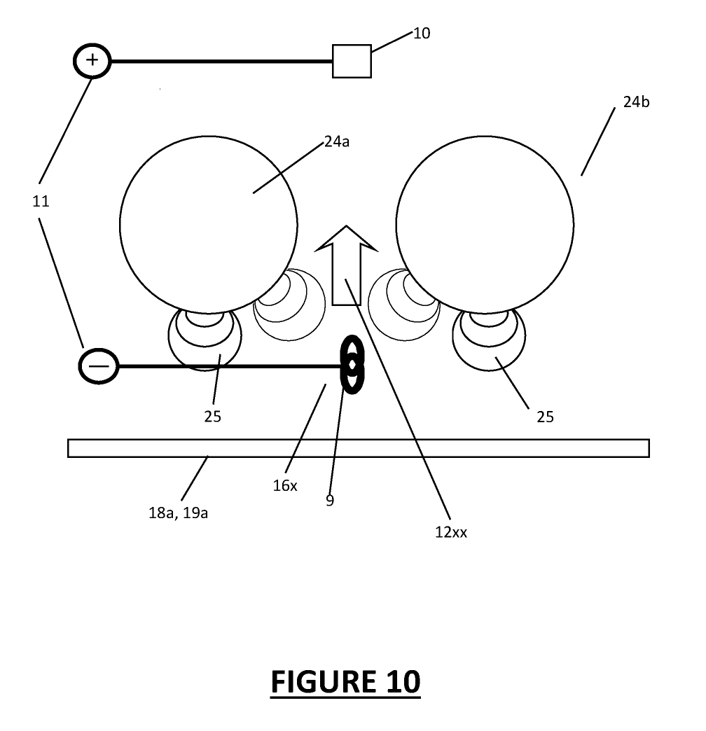

Variations, of course, are possible: such as element 17, which could be static or dynamic, and of different geometry, for example it could be a planar target as the one in this Figure of a rotatable cylindrical in nature as those of FIGS. 9 and 10.

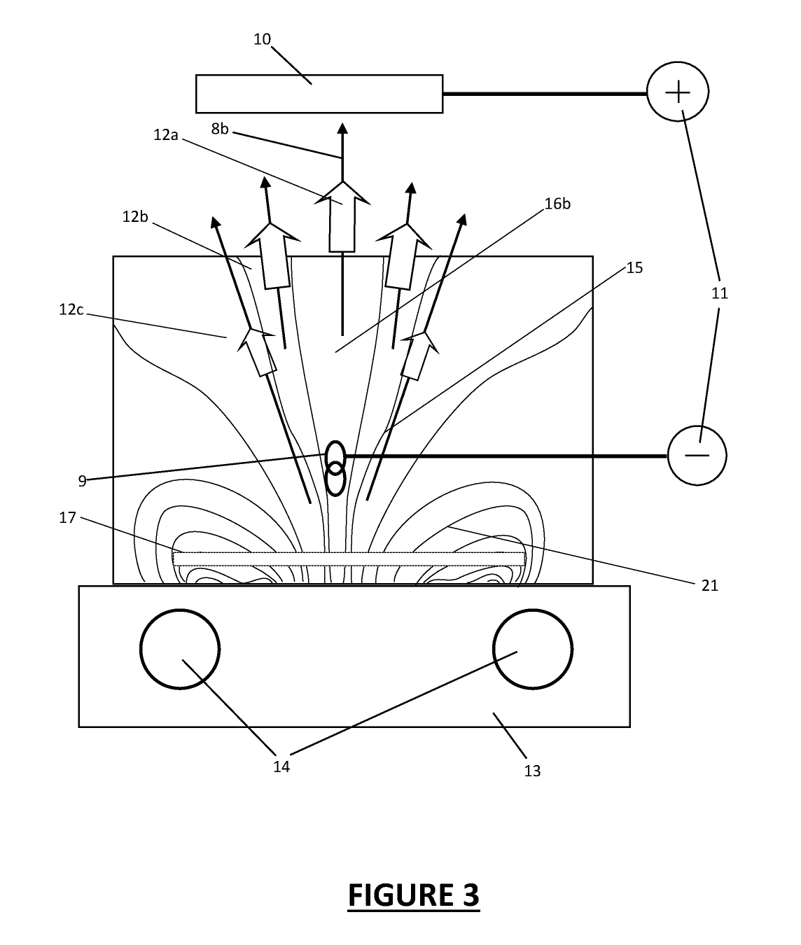

FIG. 3 is a schematic diagram representing another embodiment of the present invention. Comparing the embodiment of FIG. 3 with that of FIG. 2, this device exhibits a different magnetic field induced by magnetic means contained in 13 at different setpoints of magnetic elements 14.

The device 13 is able to control electron emission and plasma projection.

In such device, a thermionic emitter 9 is placed in a partially evacuated atmosphere and in an area of magnetic field where there is no or little confinement. Electrons emitted by thermionic emitter 9 are guided towards the anode element 10 by a channeling path 16b created by the magnetic field lines 15.

Thermionic emitter 9 is biased negatively with respect to the anodic element 10 via a suitable power supply 11. A negatively biased element 17 could be used in order to enhance electron emission. In addition, magnetic field trap 21 could be varied by magnetic means 14.

In addition, biasing on the element 17 could be able to sustain a plasma discharge and/or an electron emission and/or ionised particles and/or neutral particles with at least some of those particles having energies above 5 eV.

In the embodiment of FIG. 3, there is no large confinement of electrons around the thermionic emitter 9 as the electrons are repelled from negatively biased element 17 and via the magnetic field lines 15, and channeled away via zone 16b towards the anode 10.

Collision between electrons and gas and/or other elemental and/or molecular 8b particles present in the vacuum produces a degree of ionisation and ionised particles will be guided by the flow of electrons towards the anode.

Due to the lack of confinement, the resulting ionisation flux in direction 12a will be of a lesser degree to that of FIG. 2. Other ionised particles could follow a different type of distribution such as in directions 12b-12c mainly based on the energy and momentum conservation and collisions occurring in the process.

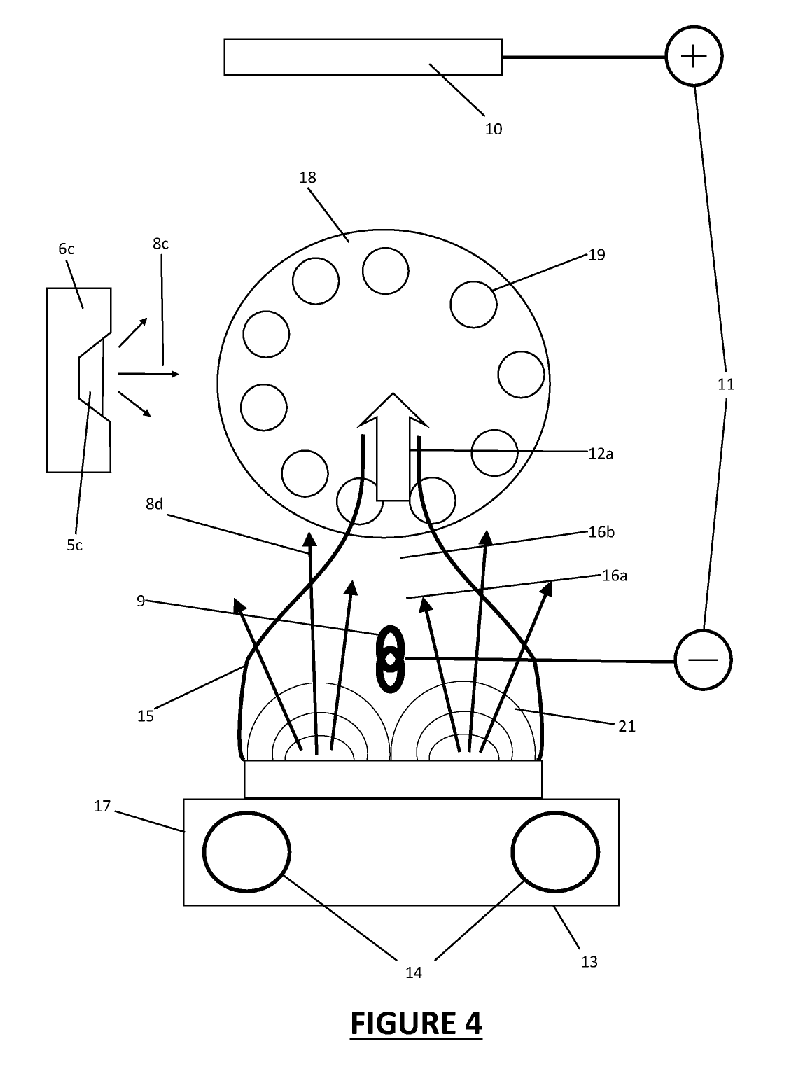

FIG. 4 is a schematic diagram representing another embodiment of the present invention where a device as described in FIG. 2 and FIG. 3 is also in the presence of another coating element 6c containing elements 5c, which produces evaporated flux 8c in a partially evacuated atmosphere.

The coating, ionisation and control device 13 is able to control electron emission and plasma in this embodiment. In such device, a thermionic emitter 9 is placed and in an area of magnetic field confinement 16a. Thermionic emitter 9 is biased negatively with respect to the anodic element 10 via suitable power supply 11.

Electrons emitted by thermionic emitter 9 are essentially trapped by magnetic field lines 21 and 15 and negatively biased element 17. In addition, magnetic field trap 21 could be varied by magnetic means 14.

In addition, biasing on the element 17 could be able to sustain a plasma discharge and/or an electron emission and/or ionised particles and/or neutral particles with at least some of those particles having energies above 5 eV. The confinement of electrons around the thermionic emitter 9 are such that the electrons are channeled towards the anode 10 via a guided path 16b created by the magnetic field lines 15.

Element 17 is biased in such a way as a substantial amount of vapour phase sputtering flux 8d is created. Collision between electrons and gas and/or other elemental and/or molecular particles 8d present in the vacuum produces a degree of ionisation and ionised particles are guided by the flow of electrons towards the anode: creating a mayor ionisation flux 12a. Other ionised particles could follow a different type of distribution based on the energy and momentum conservation and collisions occurring in the process. In this embodiment, the flux 12a and 8c are able to bring the particles into a zone of deposition where substrate carrier 18 and/or spindles 19 elements could get coated as they rotate.

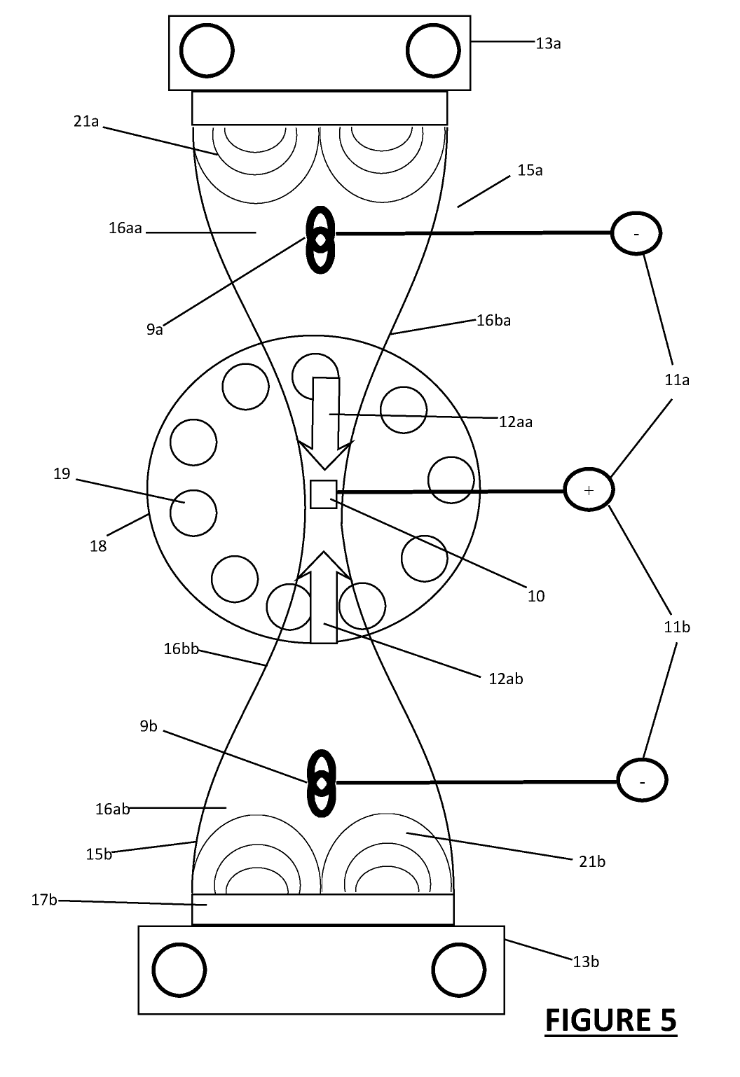

FIG. 5 is a schematic diagram representing another embodiment of the present invention, where two coaters (such as previously described) 13a and 13b have such a magnetic interaction that are able to create an enhanced electron confinement over a large area covering the substrate elements 18 and 19 as they rotate.

The coaters 13a and 13b are able to control electron emission and plasma in this embodiment.

In such device, the respective thermionic emitters 9a and 9b are placed in the respective areas of magnetic field confinements 16ab and 16ab. Thermionic emitters 9a and 9b are respectively biased by power supplies 11a and 11b with respect to an essentially centrally placed biased anodic element 10.

Electrons emitted by thermionic emitters 9a and 9b are essentially trapped by magnetic field lines 21a-b and 15a-b and negatively biased elements a-b 17. Suitable biasing on the elements 17a-b could be able to sustain a plasma discharge and/or an electron emission and/or ionised particles and/or neutral particles with at least some of those particles having energies above 5 eV.

The confinement of electrons around the thermionic emitters 9a-b is such that the electrons are channeled towards the anode 10 via a guided paths 16b created by the magnetic field lines 15a-b. Similarly to previously described embodiments, the ionised particles are guided by the flow of electrons towards the anode: creating a mayor ionisation fluxes 12aa and 12ab. Substrate carrier 18 and/or spindles 19 elements could also be coated as they rotate.

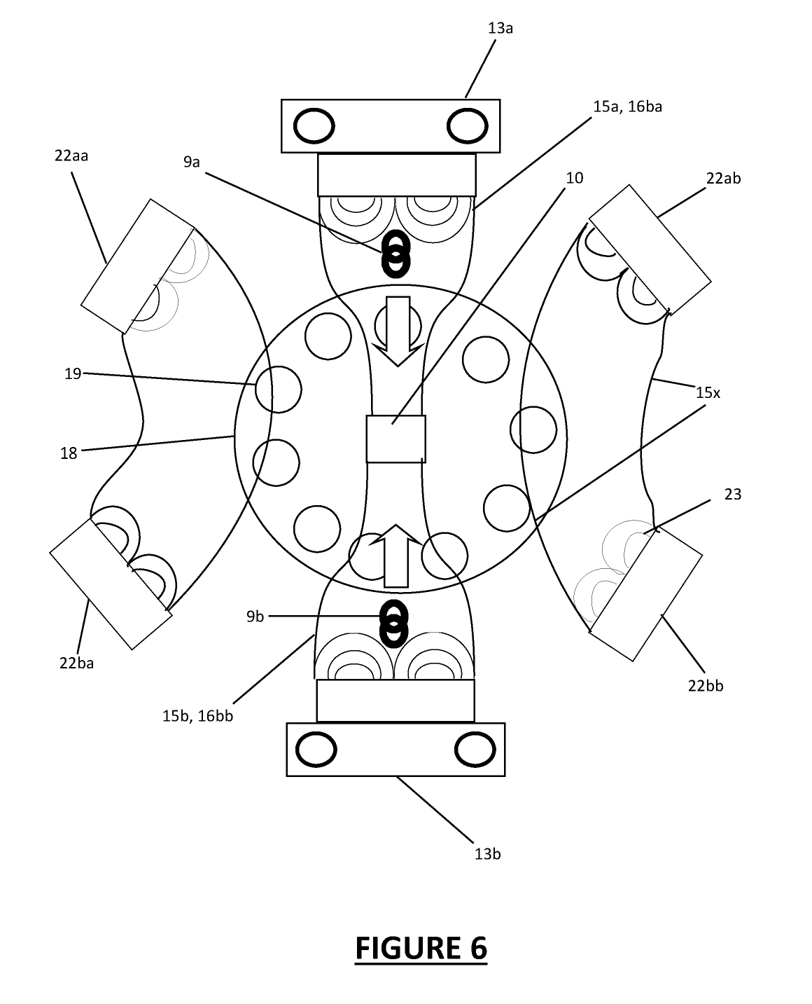

FIG. 6 is a schematic diagram representing another embodiment of the present invention, where two coaters 13a and 13b, such as those described above with reference to FIG. 5 are combined with other coating elements 22aa, 22ab, 22ba and 22bb.

In this embodiment, magnetic interactions are such that magnetic links 15x are established between different magnetic elements creating areas of magnetic confinement over substrate elements 18 and 19.

The coaters 13a and 13b are able to control electron emission and plasma in this embodiment. In such device, the respective thermionic emitters 9a and 9b are placed in the respective areas of magnetic field confinements 16ab and 16ab. Thermionic emitters 9a and 9b are respectively biased by power supplies 11a and 11b with respect to an essentially centrally placed biased anodic element 10. Electrons emitted by the cathodic elements/thermionic emitters 9a and 9b are essentially trapped by magnetic field lines, and channel towards the substrate elements 18 and 19 via field lines and channels 15a, 15b, 16ba and 16bb.

Similarly to previously described embodiments, the ionised particles are guided by the flow of electrons towards the anode creating a mayor ionisation fluxes towards the substrate. In addition, coating units, such as magnetron sputtering sources with respective trapped plasma field lines 23 responsible for creating sputtering condition trap as in the case of this FIG. 6, will bring coating towards substrate carrier 18 and/or spindles 19 elements as they rotate.

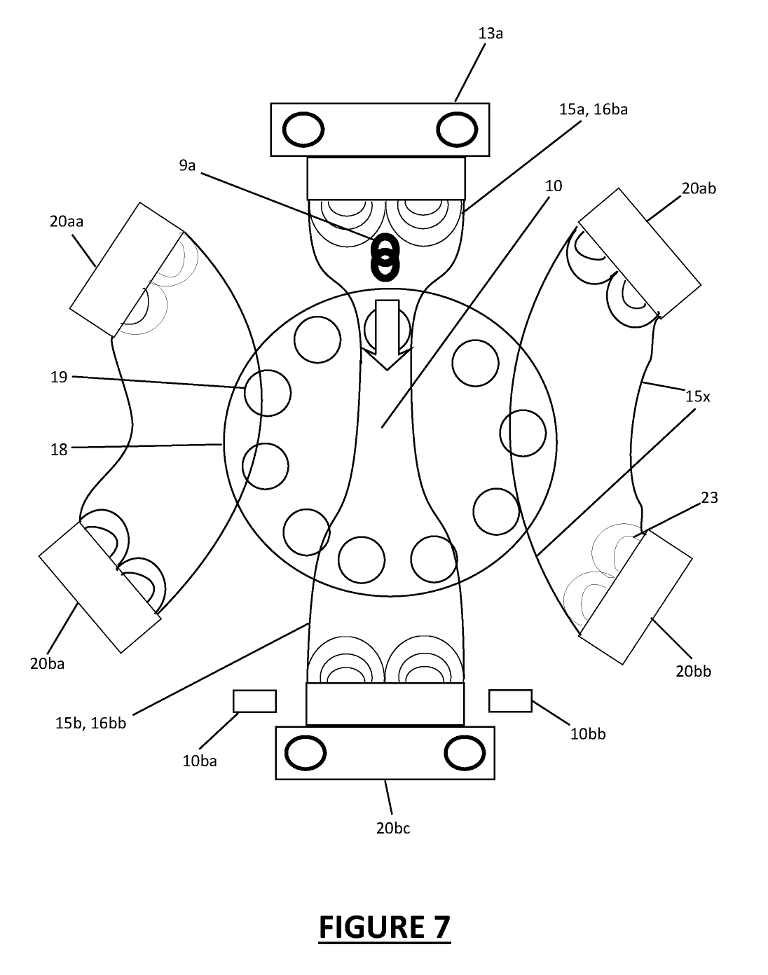

FIG. 7 is a schematic diagram representing another embodiment of the present invention which is similar to the embodiment described in FIG. 6, but where one of the ionisation elements has been replaced by an additional coating element 20bc, which magnetically links to ionisation device 13a.

As in the embodiment described above in relation to FIG. 5, coating elements 22aa, 22ab, 22ba and 22bb are arranged so that a magnetic link brings electron confinement lines 15x covering substrate elements 18 and 19 as they rotate.

The coater 13a is able to control electron emission and plasma in this embodiment. In such device, the thermionic emitter 9a is placed in the area of magnetic field confinement and guidance 16ba. Anodic elements 10ba, bb are placed off-centre (substantially not central) in the deposition system—in such a way that the electrons injected via thermionic emitter 9a, when travelling towards the anodic elements 10ba and 10bb, will bring ionisation along the way in the substrate zone.

In addition, coating units, such as magnetron sputtering sources of this embodiment present respective trapped plasma field lines 23 responsible for creating sputtering condition trap. During the sputtering, as in the case of this FIG. 6 will bring coating towards substrate carrier 18 and/or spindles 19 elements as they rotate.

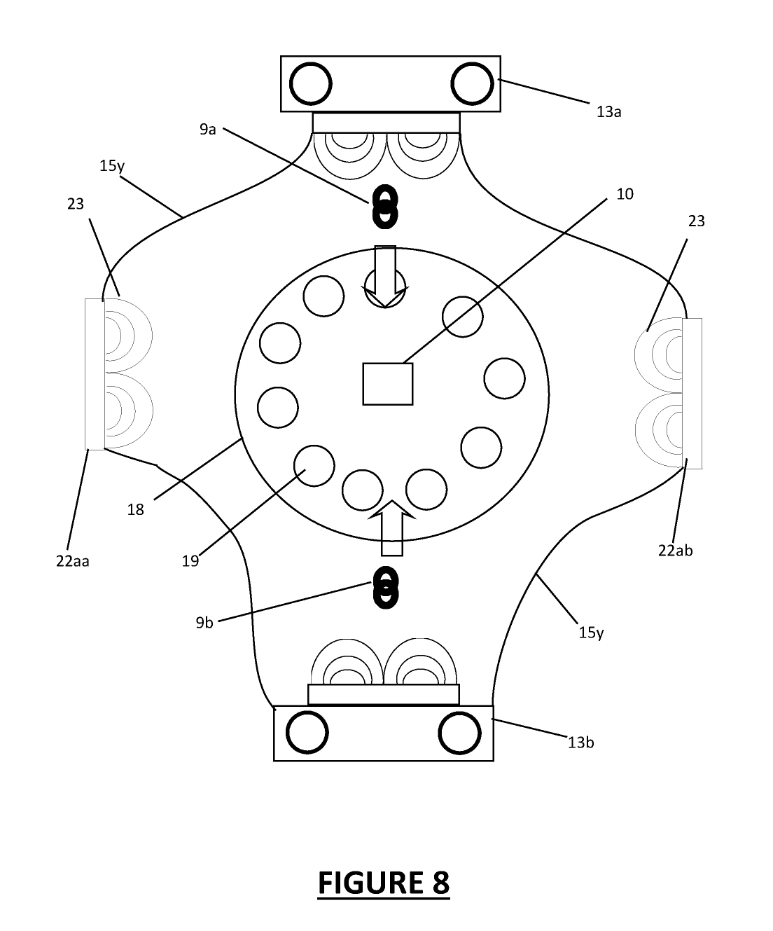

FIG. 8 is a schematic diagram representing another embodiment of the present invention which is similar to the embodiment described in FIG. 6, but where different plasma sources are linked in such a way by magnetic field lines 15y that form a closed confinement for the electron injection over a large area on substrate elements 18 and 19.

The coaters 13a and 13b, similar to previously described embodiments, contain thermionic emitters 9a and 9b respectively responsible for electron injection into the confinement area. By suitable biasing with respect to anodic element 10. Coating devices 22aa and 22ab have confinement zones 23 suitable for magnetron sputtering plasma trap condition. Sputtering will produce deposition from target material pertinent to coating devices 22aa and 22ab.

FIG. 9 is a schematic diagram representing another embodiment of the present invention, which is related to a rotatable cylindrical cathode with ionisation enhancement.

Coaters 24a and 24b have a magnetic field such that a zone of substantially zero field strength 16x is created. In such zone, a thermionic emitter 9 is placed with a negative bias with respect to anodic elements 10a and 10b with power supplies 11a and 11b. By suitable angling of the magnetic array within devices 24a and 24b, the main magnetic traps 25 are such as the sputtering coating flux could be made essentially passed through the ionisation zone 16x creating ionised fluxes 12xa and 12xb.

Substrate 18a, 19a-usually moving in one direction or in reciprocating mode—will receive coating from both ionised and non-ionised species. Magnetic field traps 25 also assist the electron injection confinement as well as fulfilling the sputtering conditions on cathode elements 24a and 24b.

The number of rotatable cathodes could be just one, for example 24a or any plurality of such cathodes. Equally, one or more anodic elements and cathode electron injection elements could be present.

Finally, FIG. 10 is a schematic diagram representing another embodiment of the present invention, which is related to rotatable cylindrical cathode with ionisation enhancement.

Coaters 24a and 24b have a magnetic field such that a zone of substantially zero field strength 16x is created. In such zone 16x, a thermionic emitter 9 is placed with a negative bias with respect to anodic element 10 with power supplies 11.

By suitable angling of the magnetic array within devices 24a and 24b, the main magnetic traps 25 are such as the electron injection feeds into the magnetron traps and the ionised flux 12xx is guided away from substrate 18a,19b.

This particular configuration may reduce the bombardment of highly energetic species on the substrate. This device configuration is especially useful for transparent conductive oxide depositions, such as those of ITO and AZO. Again, the number of rotatable cathodes could be just one, for example 24a or any plurality of such cathodes. Equally, one or more anodic elements and cathode electron injection elements could be present.

The scope of the invention is determined by the appended claims, and is not restricted to details of the foregoing embodiments, which are merely exemplary. In particular, any dimensions, materials, process conditions etc. whether explicit or implicit, could be various without departing from the scope of this disclosure.

1-42. (canceled)

43. A coater comprising:
a vapor supply;
a thermionic emitter located adjacent to, but spaced apart from, the vapor supply;
an anode located on an opposite side of the thermionic emitter to the vapor supply;
biasing means adapted in use, to negatively bias the thermionic emitter with respect to the anode; and
magnetic means adapted, in use, to create a magnetic field;
wherein the magnetic field comprises:
a region of low magnetic field strength around the thermionic emitter; and
a region of magnetic field extending between the vapor supply and the anode, such that, in use:
electrons emitted by the thermionic emitter:
interact with the vapor supply to cause emission of a vapor from the vapor supply and at least partially ionize the vapor from the vapor supply—thereby forming an at least partially ionized vapor flux; and
are attracted to the anode, thereby forming an electron flux towards the anode, the electron flux being at least partially confined within the region of magnetic field extending between the vapor supply and the anode;
and wherein:
the resulting at least partially confined electron flux interacts with the at least partially ionized vapor flux to guide the latter in a direction towards the anode and preferentially along a path corresponding to the region of magnetic field extending between the vapor supply and the anode.

44. The coater of claim 43, wherein the magnetic field comprises a magnetic field trap, which comprises a region of magnetic confinement having a very low, near-zero or zero magnetic field strength, bounded by a region of relatively higher magnetic field strength, the region of relatively higher magnetic field strength forming a plasma trap around the region of magnetic confinement, which inhibits or prevents the electron flux, and hence the at least partially ionized vapor flux from entering it.

45. The coater of claim 43, wherein the magnetic field comprises, or forms, an electron magnetic mirror comprising at least one magnet configured, in use, to deflect electrons of the electron flux from a relatively high density magnetic field region towards a relatively lower density magnetic field region, the electron magnetic mirror being configured to reverse the direction of electrons of the electron flux from substantially towards the vapor supply to substantially towards the anode.

46. The coater of claim 44, wherein the magnetic field comprises, or forms, an electron magnetic mirror comprising at least one magnet configured, in use, to deflect electrons of the electron flux from a relatively high density magnetic field region towards a relatively lower density magnetic field region, the electron magnetic mirror being configured to reverse the direction of electrons of the electron flux from substantially towards the vapor supply to substantially towards the anode.

47. The coater of claim 43, wherein the region of low magnetic field strength around the thermionic emitter comprises any one or more of the group comprising: a region of magnetic confinement having a very low, near-zero or zero magnetic field strength; and a region of low, near-zero or zero magnetic field strength.

48. The coater of claim 43, wherein the region of magnetic field extending between the vapor supply and the anode is any one or more of the group comprising: a region of low, near-zero or zero magnetic field strength; and a region of relatively higher magnetic field strength than the magnetic field strength of the region of low magnetic field strength around the thermionic emitter.

49. The coater of claim 43, wherein the thermionic emitter is cathodic with respect to the anode, the biasing means being adapted in use, to negatively bias the thermionic emitter with respect to the anode, thereby creating an electric field between the thermionic emitter and the anode.

50. The coater of claim 43, wherein the thermionic emitter comprises a filament made of any one of more of the group comprising: tungsten; a boride; ZrB2; TiB2; FeCrAl alloy; molybdenum; a silicide; MoSi2; a carbide; and SiC, which filament emits electrons when heated by passing an electrical current through it.

51. The coater of claim 43, wherein the vapor supply comprises any one or more of the group comprising: a target manufactured from a material to be coated onto a substrate; and a crucible containing a material to be coated onto a substrate.

52. The coater of claim 43, wherein the interaction between the electrons emitted by the thermionic emitter and the vapor supply to cause the emission of the vapor from the vapor supply comprises any one or more of the group comprising: thermal evaporation; electron beam evaporation; sputtering; magnetron sputtering; gas injection; and vapor injection.

53. The coater of claim 43, wherein the vapor flux comprises a vapor of material, being any one or more of the group comprising: a molecular vapor; a vapor of atoms; and a vapor of a compound.

54. The coater of claim 43, wherein the biasing means comprises any one of more of the group comprising: a DC power supply; a high-voltage DC power supply; and an AC power supply, operatively connected to the anode and thermionic emitter.

55. The coater of claim 43, further comprising an electrode located on an opposite side of the vapor supply from the thermionic emitter, the electrode being cathodic or anodic with respect to the thermionic emitter.

56. The coater of claim 43, further comprising a means for retaining a substrate to be coated by the flux of material evaporated from the supply of material to be evaporated, the means for retaining comprising any one or more of the group comprising: a fixed substrate holder; a moving substrate holder; a linearly-moving substrate holder; a rotationally moving substrate holder; a carousel; and a multi-axis carousel.

57. The coater of claim 56, further comprising a secondary source of a secondary material to be evaporated, which emits a flux of the secondary material towards the substrate.

58. The coater of claim 43, further comprising: a housing enclosing the evaporator; a vacuum pump for at least partially evacuating the housing; and a gas delivery system for at least partially filling the housing with a process gas, the process gas comprises any one or more of the group comprising: a non-inert gas; O2; and N2.

59. The coater of claim 43, wherein the magnetic means comprises any one or more of the group comprising: one or more permanent magnets; one or more electromagnets; and one or more ferromagnetic elements that modify, in use, the shape of the magnetic field.

60. A system comprising a plurality of the coaters according to claim 43, the plurality of the coaters being arranged such that their respective regions of magnetic field extending between their respective vapor supplies and their respective anodes converge.

61. The system of claim 60, comprising a common anode shared by one or more of the plurality of the coaters.

62. The system of claim 60, further comprising a supplementary magnetic means adapted, in use, to modify the shape of the respective magnetic fields of the plurality of the coaters.
